(19) United States
(12) Patent Application Publication
(10) Pub. No.: US 2017/0047276 A1
(43) Pub. Date: Feb. 16, 2017

(54) SEMICONDUCTOR DEVICE PACKAGE AND METHOD OF MANUFACTURING THE SAME

(71) Applicant: Advanced Semiconductor Engineering, Inc., Kaohsiung (TW)

(72) Inventors: Chien-Hua CHEN, Kaohsiung (TW); Teck-Chong LEE, Kaohsiung (TW); Chi-Han CHEN, Kaohsiung (TW); Sheng-Chi HSIEH, Kaohsiung (TW)

(21) Appl. No.: 14/825,326

(22) Filed: Aug. 13, 2015

(51) Int. Cl. H01L 23/498; H01L 21/48; H01L 21/56; H01L 23/31

(52) U.S. Cl. CPC H01L 23/49838; H01L 23/49827; H01L 23/3128; H01L 21/486; H01L 21/563

(57) ABSTRACT

The present disclosure relates to a semiconductor device package and a method for manufacturing the same. The semiconductor device package comprises a substrate, a first patterned conductive layer, an insulator layer, a second patterned conductive layer, and a dielectric layer. The first patterned conductive layer is disposed on a surface of the substrate. The insulator layer is disposed on the surface of the substrate and covers the first patterned conductive layer. The second patterned conductive layer is fully encapsulated by the insulator layer. The dielectric layer is disposed on the insulator layer.

### BACKGROUND

1. Technical Field

The present disclosure relates to a semiconductor device package and a method of manufacturing the same. In particular, the present disclosure relates to a semiconductor device package having integrated passive devices and a method of manufacturing the same.

2. Description of the Related Art

Semiconductor devices have become progressively more complex, driven at least in part by the demand for smaller sizes and enhanced processing speeds. At the same time, there is a demand to further miniaturize many electronic products containing these semiconductor devices.

However, miniaturization of semiconductor devices can adversely affect performance of semiconductor devices. It would be desirable to reduce the space occupied by semiconductor devices without compromising the performance thereof.

### SUMMARY

In accordance with an embodiment of the present disclosure, a semiconductor device package comprises a substrate, a first patterned conductive layer, an insulator layer, a second patterned conductive layer, and a first dielectric layer. The first patterned conductive layer is disposed on a surface of the substrate. The insulator layer is disposed on the surface of the substrate and covers the first patterned conductive layer. The second patterned conductive layer is encapsulated by the insulator layer. The first dielectric layer is disposed on the insulator layer.

In accordance with another embodiment of the present disclosure, a method of manufacturing a semiconductor device comprises: providing a substrate; forming a first patterned conductive layer on a surface of the substrate; forming a second patterned conductive layer on the substrate to cover the first patterned conductive layer; oxidizing the second patterned conductive layer to form a first insulator layer; forming a third patterned conductive layer on the insulator layer; removing a portion of the third patterned conductive layer; forming a fourth patterned conductive layer to cover the first insulator layer and a remaining portion of the third patterned conductive layer; and oxidizing the fourth patterned conductive layer to form a second insulator layer.

### BRIEF DESCRIPTION OF THE DRAWINGS

FIG. 1 is a cross-sectional view of a semiconductor device package in accordance with an embodiment of the present disclosure.

FIG. 2 is a cross-sectional view of a semiconductor device package in accordance with an embodiment of the present disclosure.

FIG. 3A, FIG. 3B, FIG. 3C, FIG. 3D, FIG. 3E, FIG. 3F, FIG. 3G, FIG. 3H, FIG. 3I, FIG. 3J, FIG. 3K, FIG. 3L, FIG. 3M and FIG. 3N illustrate a method of manufacturing a semiconductor device package in accordance with an embodiment of the present disclosure.

FIG. 4 is a perspective view of a semiconductor device package in accordance with an embodiment of the present disclosure.

FIG. 5 is a schematic circuit diagram of a semiconductor device package in accordance with an embodiment of the present disclosure.

FIG. 6 provides a plot of signals simulated for the circuit of FIG. 5.

FIG. 7 provides plots of signals simulated for the circuit of FIG. 5.

Common reference numerals are used throughout the drawings and the detailed description to indicate the same or similar elements. Embodiments of the present disclosure will be more apparent from the following detailed description taken in conjunction with the accompanying drawings.

### DETAILED DESCRIPTION

It is desirable to provide a relatively small semiconductor device with good performance. It is also desirable to provide passive devices, such as capacitors, within the small semiconductor device.

Spatial descriptions, such as “above,” “below,” “up,” “left,” “right,” “down,” “top,” “bottom,” “vertical,” “horizontal,” “side,” “higher,” “lower,” “upper,” “over,” “under,” and so forth, are specified with respect to a certain element or certain plane of an element, as described in the specification, and apply to the orientation shown in the applicable figure(s). Furthermore, it should be understood that the spatial descriptions used herein are for purposes of illustration only, and that practical implementations of the structures described herein can be spatially arranged in any orientation or manner, provided that the merits of embodiments of this disclosure are not deviated by such arrangement.

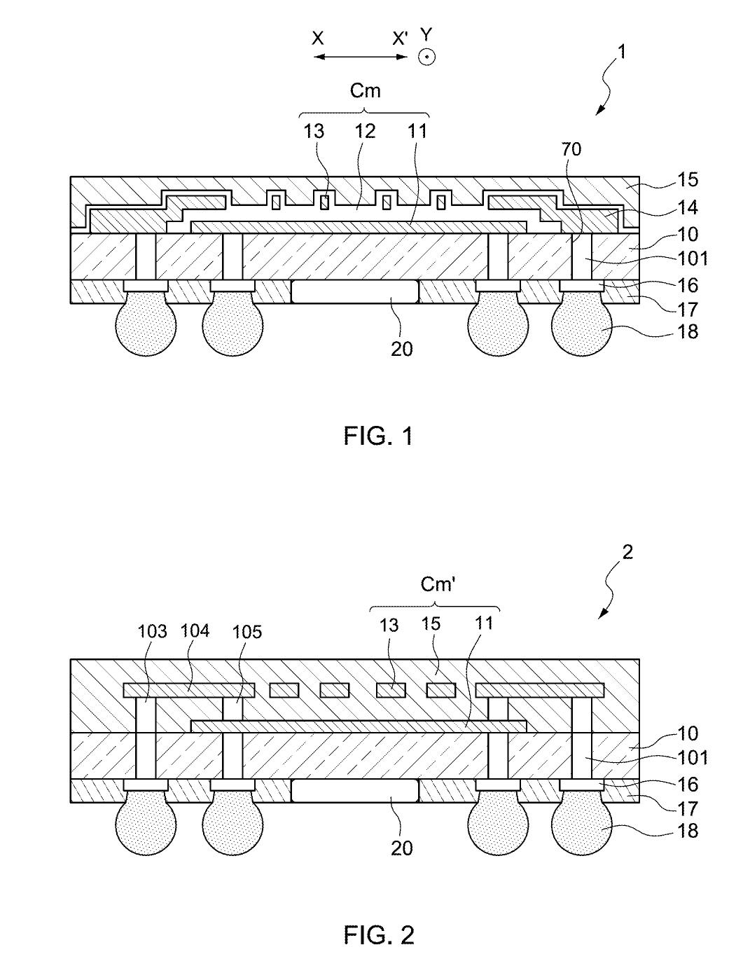

FIG. 1 is a cross-sectional view of a semiconductor device package 1 in accordance with an embodiment of the present disclosure. The semiconductor device package 1 includes a substrate 10, patterned conductive layers 11, 13 and 14, an insulator layer 12, dielectric layers 15 and 17, conductive pads 16, conductive posts 101, conductive materials 18, and a die 20.

In one or more embodiments, the substrate 10 includes one of, or a combination of, glass, silicon, or silicon dioxide (SiO₂). In other embodiments, other materials may be used.

The conductive posts 101 extend from a first surface of the substrate 10 (the upper surface in the orientation of FIG. 1) to a second surface of the substrate 10, and electrically connect circuits on the first surface with circuits on the second surface. In one or more embodiments, the conductive posts 101 include copper or another suitable metal or alloy. In other embodiments, other conductive materials are used.

The conductive pads 16 are disposed on the second surface of the substrate 10, and the conductive posts 101 are electrically connected to the conductive pads 16. In one or more embodiments, the conductive posts 101 are directly physically connected to the conductive pads 16. In one or more embodiments, the conductive pads 16 include aluminum or another suitable metal or alloy. In other embodiments, other conductive materials are used.

The die 20 is disposed on the second surface of the substrate 10. The dielectric layer 17 is disposed on the second surface of the substrate 10, and covers portions of the conductive pads 16 and a perimeter of the die 20. The die 20 and the remaining portions of the conductive pads 16 are exposed by the dielectric layer 17. In one or more embodiments, the dielectric layer 17 includes TMMR® (manufactured by Tokyo Ohka Kogyo CO., LTD.) In other embodiments, the dielectric layer 17 includes a polyimide (PI) or another suitable dielectric material.

The conductive material 18 is disposed on the portion of each of the conductive pads 16 exposed by the dielectric layer 17. The conductive material 18 is, for example, solder.

The patterned conductive layer 11 is disposed on the first surface of the substrate 10 and is electrically connected to the conductive posts 101. In one or more embodiments, the patterned conductive layer 11 is directly physically connected to the conductive posts 101.

The patterned conductive layer 11 may include one or more traces. Each of the traces of the patterned conductive layer 11 may extend in a first direction. For example, each trace may extend along a direction XX′ shown in FIG. 1. In other embodiments, each trace may extend along another direction, or different traces may extend in different directions. Each trace of the patterned conductive layer 11 has a width of approximately 4.5 micrometer (μm) to approximately 5.5 μm. In one or more embodiments, trace spacing or pitch measured center-to-center on the traces is approximately 4.5 μm to approximately 5.5 μm for traces of the patterned conductive layer 11 in the embodiment of FIG. 1.

The insulator layer 12 is disposed on the first surface of the substrate 10. The insulator layer 12 covers the patterned conductive layers 11, 13 and 14. In one or more embodiments, a thickness of the insulator layer 12 is approximately 0.05 μm to approximately 0.6 μm. In one or more embodiments, the thickness of the insulator layer 12 is approximately 0.2 μm to approximately 0.5 μm. The insulator layer 12 may include a high permittivity material. In one or more embodiments, a permittivity of the insulator layer 12 is five times a permittivity of the dielectric layer 17. For example, the permittivity of the insulator layer 12 may be approximately 26 farads per meter (F/m) to approximately 26.5 F/m, and the permittivity of the dielectric layer 17 may be approximately 3 F/m to approximately 3.5 F/m. In one or more embodiments, the insulator layer 12 includes tantalum pentoxide (Ta₂O₅) or another suitable material.

The patterned conductive layer 13 is fully encapsulated within the insulator layer 12. The patterned conductive layer 13 may include a number of traces. Each of the traces of the patterned conductive layer 13 may extend in a same direction, which forms an angle with the direction XX′. For example, each trace of the patterned conductive layer 13 may extend along the direction “Y”, which is orthogonal or perpendicular to the direction XX′ in the embodiment of FIG. 1, but can be at another angle to the direction XX′ in another embodiment. In one or more embodiments, each of multiple ones of the traces of the patterned conductive layer 13 and each of multiple ones of the traces of the patterned conductive layer 11 intersect to form a matrix of intersections. Each trace of the patterned conductive layer 13 has a width of approximately 4.5 μm to approximately 5.5 μm. In one or more embodiments, trace spacing or pitch measured center-to-center on the traces is approximately 4.5 μm to approximately 5.5 μm for traces of the patterned conductive layer 13 in the embodiment of FIG. 1.

In the embodiment of FIG. 1, the insulator layer 12 has a cross-sectional profile with an irregular surface corresponding to profiles of portions of the patterned conductive layers 13, 14. In other embodiments, the insulator layer 12 has a substantially flat upper surface. In one or more embodiments, a thickness of the insulator layer 12 between the patterned conductive layer 13 and the patterned conductive layer 11 is approximately 0.05 μm to approximately 0.6 μm.

At some, or all, of the intersections of the traces of the patterned conductive layers 11 and 13 (e.g., in the matrix of intersections), the patterned conductive layer 11 and the patterned conductive layer 13, along with the insulator layer 12 between the patterned conductive layers 11 and 13, form a capacitor Cm. Thus, in one or more embodiments, a matrix of capacitors Cm corresponds to the matrix of intersections. For example, such a matrix of capacitors Cm may be used in a touch sensor product. In one or more embodiments, each capacitor Cm has a surface area (e.g., of the electrode plate) of approximately 4.5×4.5 μm² to approximately 5.5×5.5 μm².

The patterned conductive layer 14 is disposed on the first surface of the substrate 10 and is covered by the insulator layer 12. The patterned conductive layer 14 may be fully covered by the insulator layer 12 except for the lowermost surface of the patterned conductive layer 14. As shown in FIG. 1, the patterned conductive layer 14 extends upward and inward (in the orientation illustrated) step-wise to cover a step-like structure formed by the insulator layer 12, so that a portion of the patterned conductive layer 14 is positioned over the first patterned conductive layer 11.

In one or more embodiments, one or more of the patterned conductive layers 11, 13, and 14 include one or more of aluminum (Al), copper (Cu), or an alloy thereof, such as AlCu. One or more of the patterned conductive layers 11, 13, and 14 may be another suitable conductive material, metal or alloy. The materials used for two or more of the patterned conductive layers 11, 13, and 14 may be the same or different.

The dielectric layer 15 is disposed on the insulator layer 12. The dielectric layer 15 covers the insulator layer 12. In one or more embodiments, the dielectric layer 15 includes a material similar to, or the same as, a material of the dielectric layer 17.

FIG. 2 is a cross-sectional view of a semiconductor device package 2 in accordance with an embodiment of the present disclosure. The semiconductor device package 2 includes a substrate 10, patterned conductive layers 11, 13 and 104, dielectric layers 15 and 17, conductive pads 16, conductive posts 101, 103 and 105, conductive materials 18, and a die 20. The substrate 10, the dielectric 17, the conductive pads 16, the conductive posts 101, the conductive material 18, and the die 20 are similar to the like-numbered components described with respect to FIG. 1.

The patterned conductive layer 11 may include one or more traces. In the embodiment of FIG. 2, each trace of the patterned conductive layer 11 has a width of approximately 20 μm. In one or more embodiments, trace spacing or pitch measured center-to-center on the traces is approximately 20 μm for traces of the patterned conductive layer 11 in the embodiment of FIG. 2.

The patterned conductive layers 13 and 104 are disposed over the first patterned conductive layer 11. The patterned conductive layer 13 may include a number of traces. In one or more embodiments, each of multiple ones of the traces of the patterned conductive layer 13 and each of multiple ones of the traces of the patterned conductive layer 11 intersect to form a matrix of intersections. In one or more embodiments, each trace of the patterned conductive layer 13 has a width of approximately 20 μm. In one or more embodiments, trace spacing or pitch measured center-to-center on the traces is approximately 20 μm for traces of the patterned conductive layer 13 in the embodiment of FIG. 2.

In one or more embodiments, one or more of the patterned conductive layers 11, 13, and 104 include one or more of Al, Cu, or an alloy thereof such as AlCu. One or more of the patterned conductive layers 11, 13, and 104 may be another suitable conductive material, metal or alloy. The materials used for two or more of the patterned conductive layers 11, 13, and 104 may be the same. The materials used for each of the patterned conductive layers 11, 13, and 104 may be different.

The conductive posts 103 electrically connect the patterned conductive layer 104 to the conductive pads 16. The conductive posts 105 electrically connect the patterned conductive layer 104 to the patterned conductive layer 11.

The dielectric layer 15 is disposed on the first surface of the substrate 10 such that the conductive layers 11, 13 and 104 and the conductive posts 103 and 105 are partially or fully surrounded by the dielectric layer 15. The conductive layers 11, 13 and 104 and the conductive posts 103 and 105 are not exposed from a side surface or a top surface of the dielectric layer 15 in the embodiment of FIG. 2. In one or more embodiments, a thickness of the dielectric layer 15 is approximately 10 μm at its thickest portion. In one or more embodiments, a thickness of the dielectric layer 15 between the first surface of the substrate 10 and a bottom surface of each of the patterned conductive layers 13 and 104 is approximately 5 μm. In one or more embodiments, a thickness of the dielectric layer 15 between the patterned conductive layers 11 and 13 is approximately 3 μm to approximately 4 μm.

At some, or all, of the intersections of the traces of the patterned conductive layers 11 and 13 (e.g., in the matrix of intersections), the patterned conductive layer 11 and the patterned conductive layer 13, along with the dielectric layer 15 between the patterned conductive layers 11 and 13, form a capacitor Cm′. Thus, in one or more embodiments, a matrix of capacitors Cm′ corresponds to the matrix of intersections. For example, such a matrix of capacitors Cm′ may be used in a touch sensor product. In one or more embodiments, each capacitor Cm′ has a surface area (e.g., of the electrode plate) of approximately 20×20 μm². In one or more embodiments, a permittivity of the dielectric layer 15 is approximately 3 F/m to approximately 3.5 F/m.

A reduction in width of traces of the patterned conductive layer 13 (e.g., as shown in FIG. 1 in comparison to FIG. 2) may result in relatively more capacitors in a given area, which may improve a resolution and/or sensitivity of the sensor device. Additionally, because the insulator layer 12 has a relatively high permittivity, and because a distance between the patterned conductive layers 11 and 13 is relatively short, a reduction in width of the traces of the patterned conductive layer 13 would not significantly change the capacitance of each capacitor. Therefore, the devices and techniques described in the present disclosure provide for flexibility in circuit design.

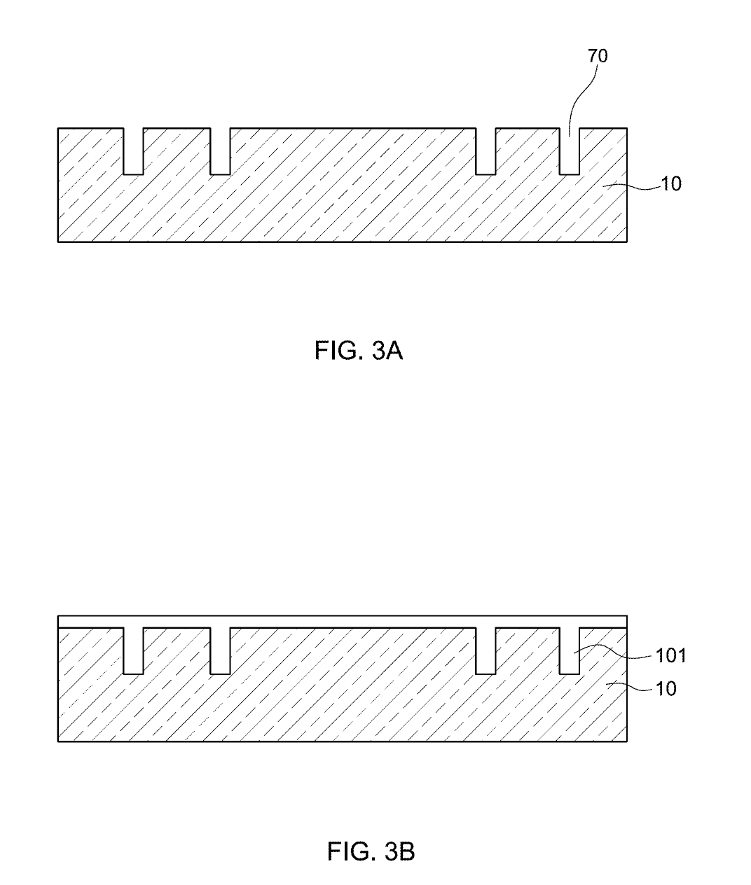

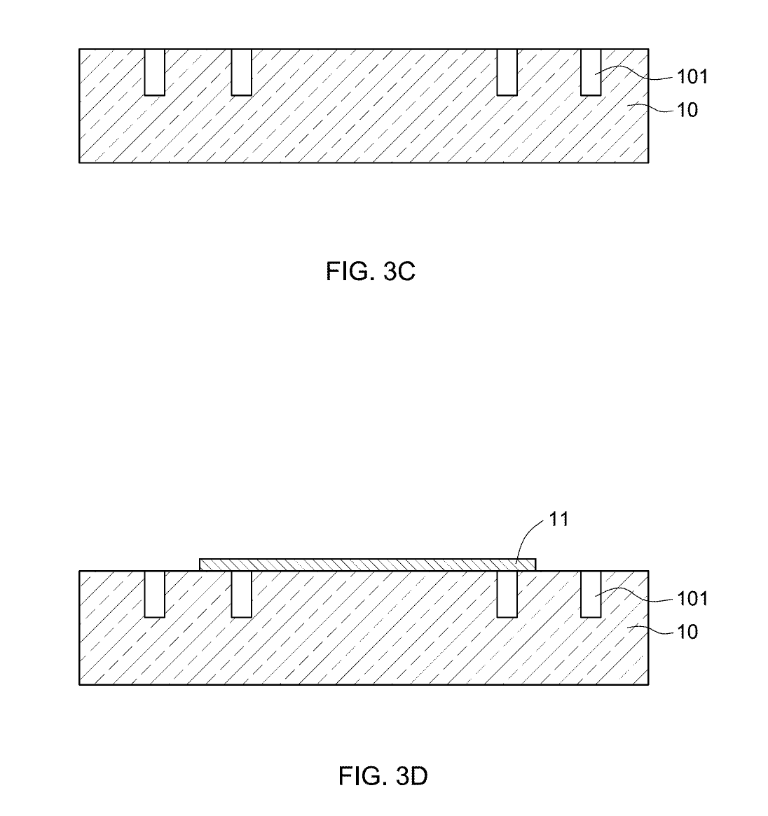

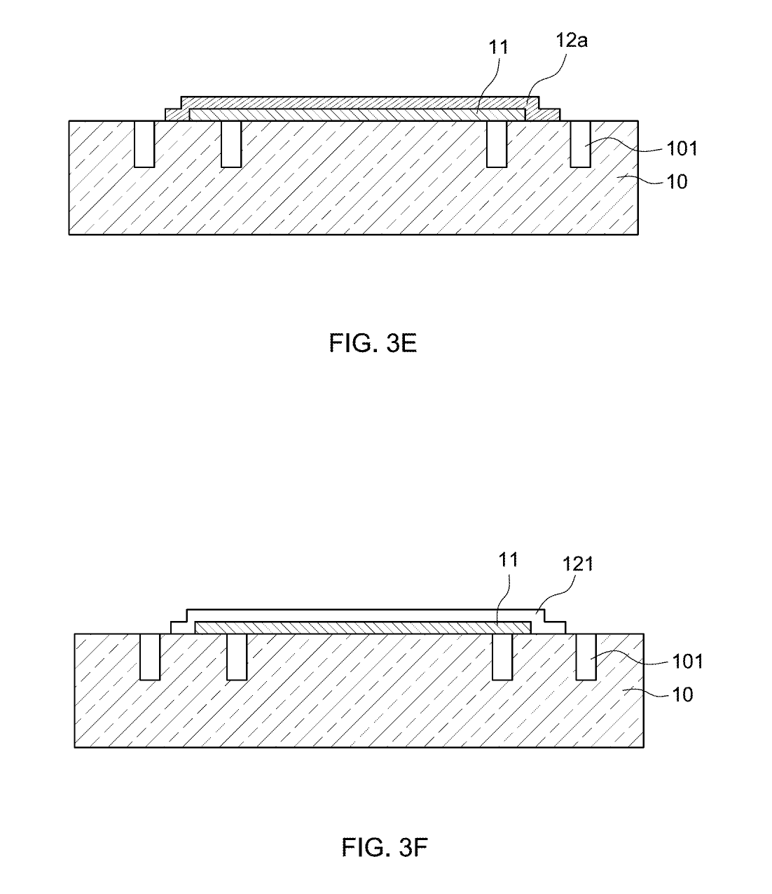

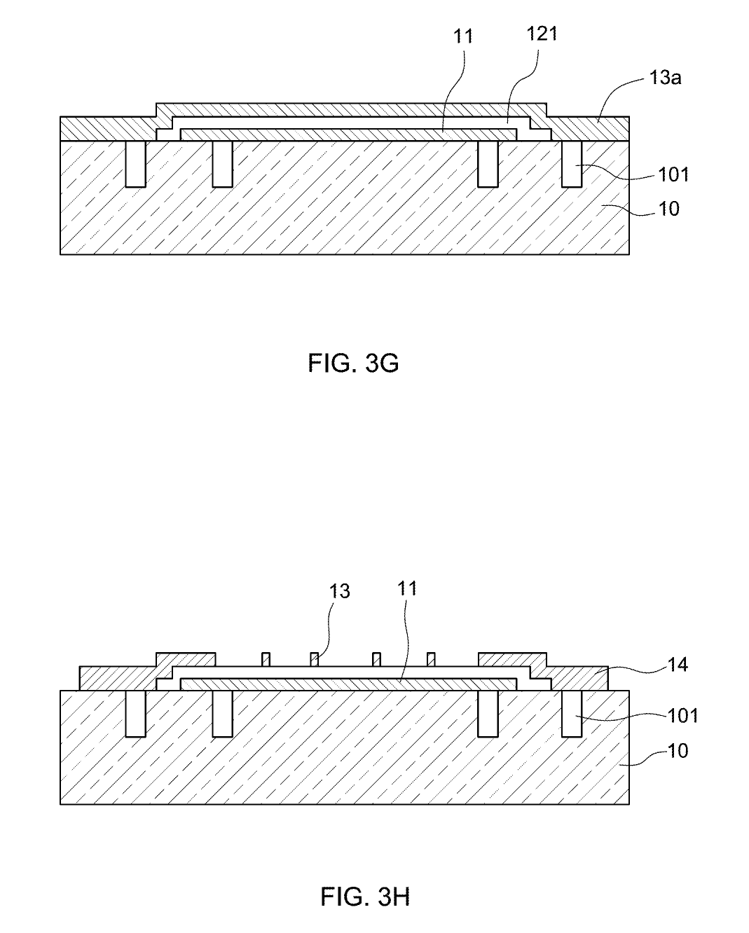

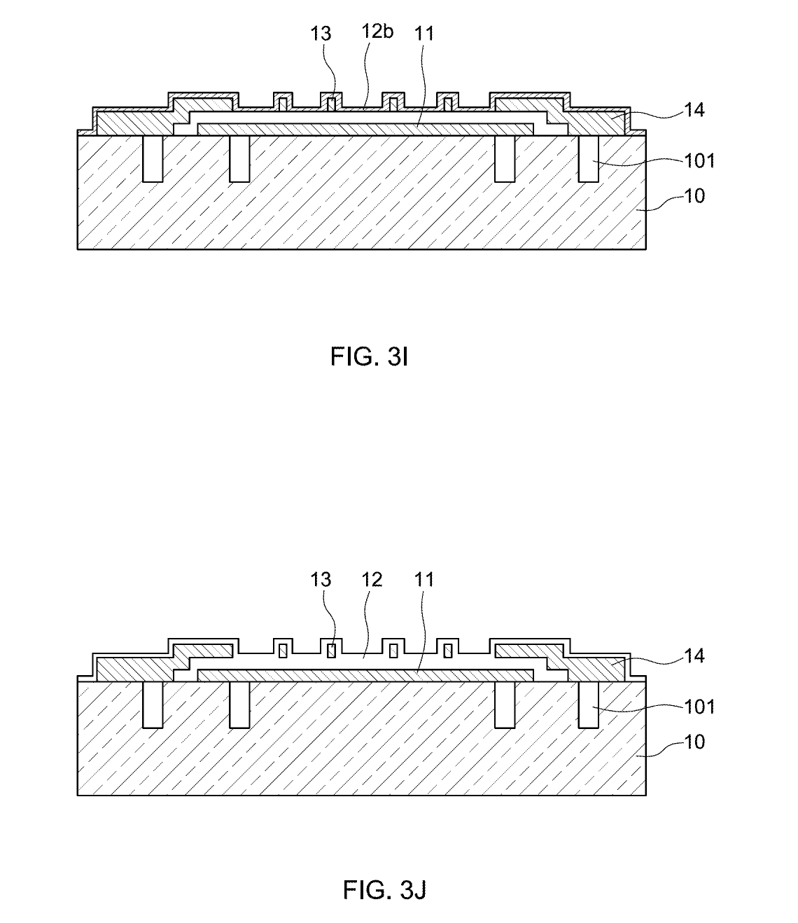

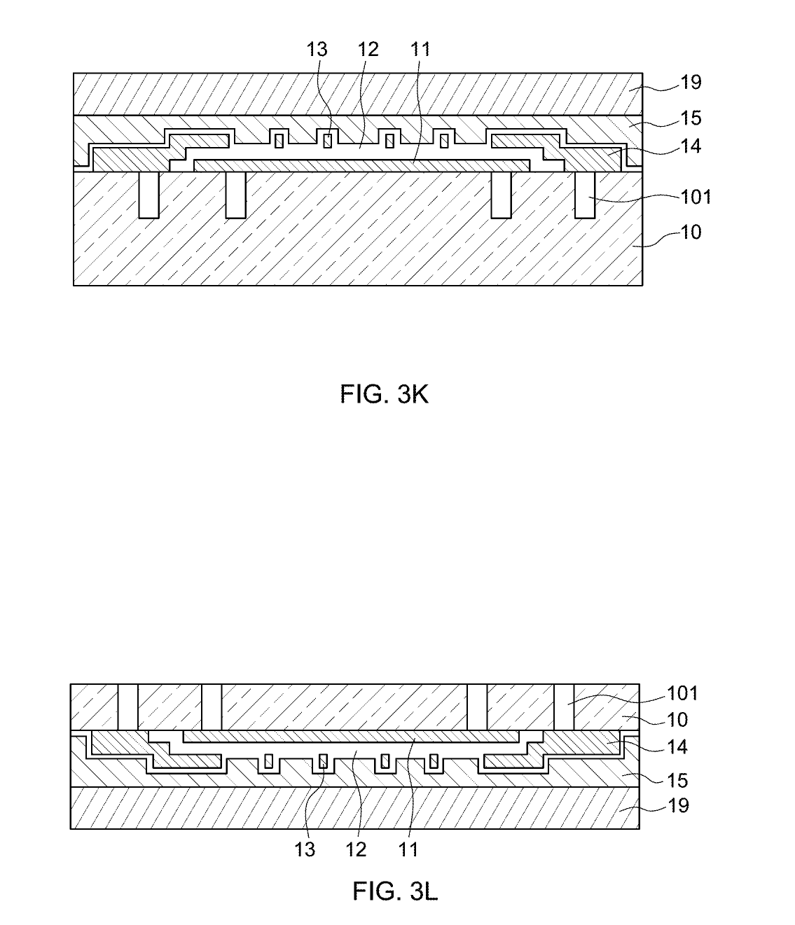

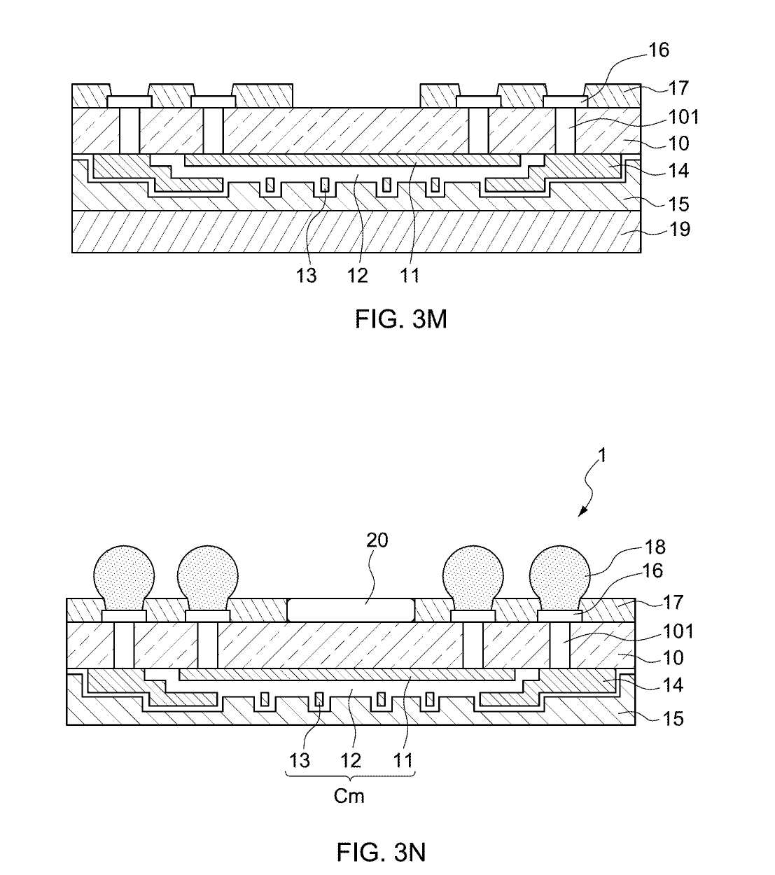

FIGS. 3A-3N illustrate a method of manufacturing a semiconductor device package, such as the semiconductor device package 1 of FIG. 1.

Referring to FIG. 3A, a substrate 10 defining a number of holes 70 is provided. In one or more embodiments, the substrate 10 includes one of glass, silicon, or SiO₂. In other embodiments, the substrate 10 includes another suitable material. The holes 70 may be formed by laser drill, etching or another suitable technique, from a first surface of the substrate 10.

Referring to FIG. 3B, a conductive material such as copper or another suitable material is applied to fill the holes 70 and thereby form a number of conductive posts 101 in the substrate 10. The conductive material may be applied, for example, using a plating technique.

Referring to FIG. 3C, the conductive material on the first surface of the substrate 10 is removed, such as by etching, chemical-mechanical planarization (CMP), or another suitable technique.

Referring to FIG. 3D, a patterned conductive layer 11 is formed on the first surface of the substrate 10 by coating, sputtering, plating, photolithography or another suitable technique, such that the patterned conductive layer 11 physically and electrically connects to ones of the conductive posts 101.

Referring to FIG. 3E, a layer 12a is formed by coating, sputtering or plating a metal on the first surface of the substrate 10 and the patterned conductive layer 11. In one or more embodiments, the layer 12a is formed by sputtering tantalum on the patterned conductive layer 11 and the first surface of the substrate 10. The layer 12a is patterned, such as by a photolithography technique, to form a patterned conductive layer 12a. The patterned conductive layer 12a in the vicinity of edges of the patterned conductive layer 11 may have a step-like structure, as shown in the embodiment of FIG. 3E.

Referring to FIG. 3F, an anodic oxidation treatment is performed on the patterned conductive layer 12a to form a metal oxide layer 121. In an embodiment in which the metal of the patterned conductive layer 12a is tantalum, the tantalum is oxidized to Ta₂O₅.

Referring to FIG. 3G, a conductive layer 13a is formed by coating, sputtering or plating a metal layer to cover the first surface of the substrate 10 and the metal oxide layer 121.

In one or more embodiments, one or both of the patterned conductive layers 11 and 13a include one or more of Al, Cu, or an alloy thereof such as AlCu. One or both of the patterned conductive layers 11 and 13a may include another suitable conductive material, metal or alloy. The materials used for the patterned conductive layers 11 and 13a may be the same or different.

Referring to FIG. 3H, a patterned conductive layer 13 and a patterned conductive layer 14 are formed using photolithography techniques on the conductive layer 13a. The patterned conductive layer 14 may have a step-like structure over the step-like structure of the metal oxide layer 121. A portion of the metal oxide layer 121 is exposed by the patterned conductive layers 13 and 14.

Referring to FIG. 3I, a layer 12b is formed by coating, sputtering or plating a metal on the first surface of the substrate 10, the patterned conductive layers 13 and 14, and the exposed portion of the metal oxide layer 121. In one or more embodiments, the layer 12b is formed by sputtering tantalum on the first surface of the substrate 10, the patterned conductive layers 13 and 14, and the exposed metal oxide layer 121.

Referring to FIG. 3J, an anodic oxidation treatment is performed on the layer 12b to form a metal oxide. In an embodiment in which the metal of the layer 12b is tantalum, the tantalum layer is oxidized to Ta₂O₅. The metal oxide layer 121 and the oxidized layer 12b together form an insulator layer 12.

Referring to FIG. 3K, a dielectric layer 15 is formed to cover the insulator layer 122. For example, the dielectric layer 15 may be formed by coating a dielectric material on the insulator layer 122. A curing process may then be performed on the coated dielectric material (e.g., at a temperature of approximately 370 degrees) to solidify the dielectric layer 15. In one or more embodiments, the dielectric layer 15 is a PI or is TMMR®. In other embodiments, the dielectric layer 15 is another suitable dielectric material.

A carrier 19 is attached to the dielectric layer 15 using an adhesive (not shown in FIG. 3K).

Referring to FIG. 3L, the substrate 10 is inverted (e.g., flipped over) such that the carrier 19 provides support for subsequent processes.

The CMP technique is used to remove a portion of the second surface (now illustrated facing upwards) of the substrate 10 to expose the conductive posts 101.

Referring to FIG. 3M, conductive pads 16 are formed over the conductive posts 101 to electrically connect to the conductive posts 101. Next, a patterned dielectric layer 17 is formed to cover portions of the second surface of the substrate 10 and portions of the conductive pads 16, and to expose the remaining portions of the second surface of the substrate 10 and the conductive pads 16. The manner of forming the dielectric layer 17 is similar to that of the formation of the dielectric layer 15. For example, the dielectric layer 17 may be patterned by photolithography and etching techniques until the portions of the conductive pads 16 and the second surface of the substrate 10 are exposed.

Referring to FIG. 3N, conductive materials 18 may be attached and electrically connected to the exposed portions of the conductive pads 16. The conductive materials 18 may be, for example, solder or another suitable metal or alloy. The die 20 is attached to an exposed portion of the second surface of the substrate 10 to form a semiconductor device package such as the semiconductor device package 1 shown in FIG. 1.

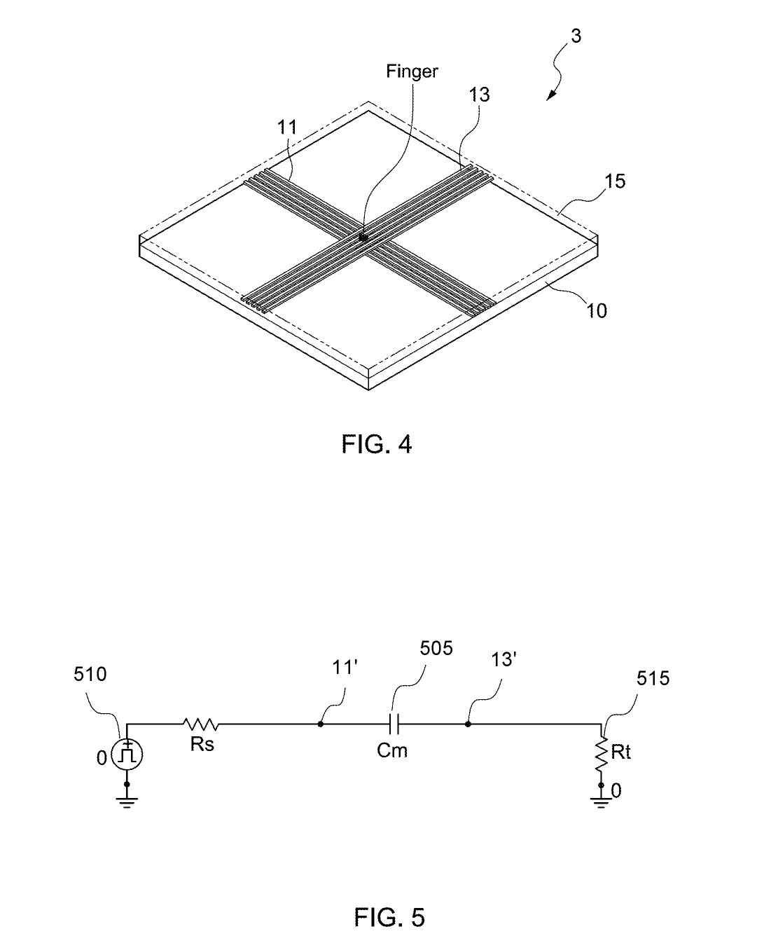

FIG. 4 is a perspective view of a semiconductor device package 3 in accordance with an embodiment of the present disclosure. In this embodiment, the semiconductor device package 3 may be used as a sensor device. The semiconductor device package 3 as illustrated in FIG. 4 may represent a portion of a semiconductor device, such as a portion of the semiconductor device package 1 of FIG. 1, for example. As can be seen from the perspective view of FIG. 4, the semiconductor device package 3 includes a substrate 10, a patterned conductive layer 11 (shown in this embodiment as including five traces), a patterned conductive layer 13 (shown in this embodiment as including five traces), and a dielectric layer 15. For clarity in the following discussion, other portions of the semiconductor device package 3 are not shown in FIG. 4, and the dielectric layer 15 is shown in outline. The patterned conductive layer 13 is disposed above, and crosses over, the patterned conductive layer 11. For explanation purposes, it is indicated in FIG. 4 that a finger may contact the dielectric layer 15 at an intersection of the patterned conductive layers 11 and 13. Such contact may cause a capacitance of one or more underlying capacitors (e.g., capacitors similar to the capacitors Cm or Cm′ of respective FIG. 1 or 2) to change. Such change may be detected by circuitry within the semiconductor device package 3 or within a device attached to the semiconductor device package 3.

FIG. 5 is a schematic circuit diagram of the semiconductor device package 1 of FIG. 1 or the semiconductor device package 2 of FIG. 2. A node 11′ represents the patterned conductive layer 11 of FIG. 1 or FIG. 2, and a node 13′ represents the patterned conductive layer 13 of FIG. 1 or FIG. 2, such that the capacitor 505 (labeled Cm″) of the schematic in FIG. 5 represents a combination of the individual capacitors Cm in FIG. 1 or Cm′ in FIG. 2. A power source 510 having an effective source resistance Rs applies a driving signal (e.g., a voltage) to the capacitor 505 at the node 11. For example, the driving signal may be a square wave. The capacitor 505 charges or discharges according to the voltage of the driving signal. A sensor 515 (represented as an effective load resistance Rt of the sensor 515) is used to sense a voltage at the node 13, which will be approximately zero at steady state. As a capacitance of the capacitor 505 changes (e.g., by a finger press as discussed with respect to FIG. 4), the voltage sensed by the sensor 515 at the node 13 will correspondingly change. Thus, a capacitive pressure sensor may be implemented by the semiconductor device package 1 or 2 of respective FIG. 1 or FIG. 2 (and similarly for the semiconductor device package 3 of FIG. 4).

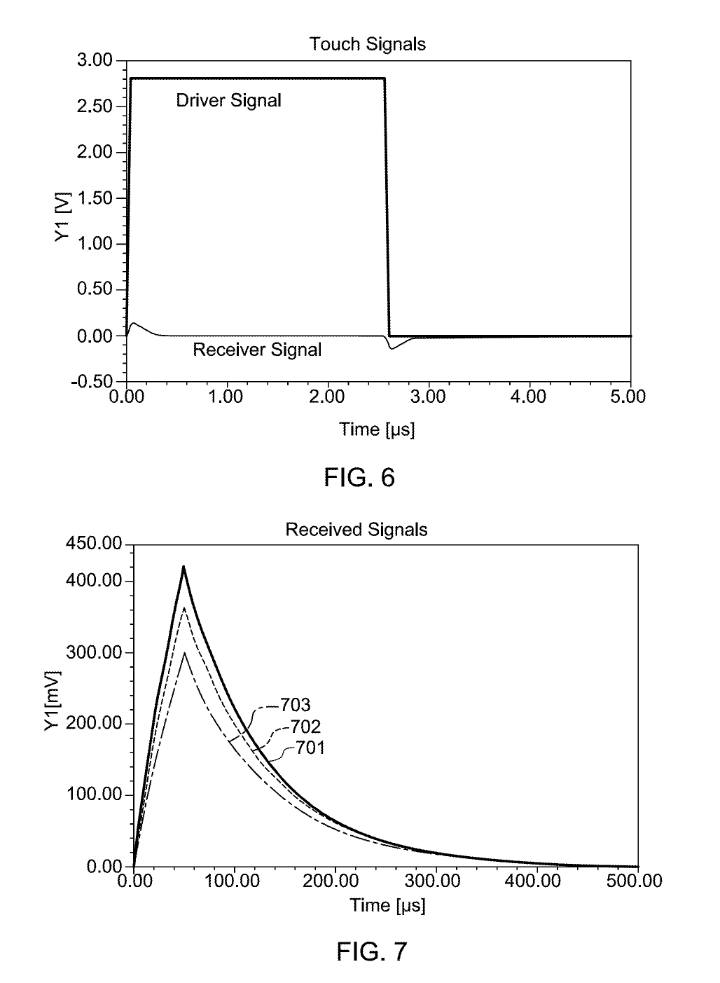

FIG. 6 is a plot of a simulation of a driving signal (“driver signal”) versus a sensed voltage (“receiver signal”) at the node 13 of FIG. 5, when the capacitance of the capacitor 505 is not changing. One pulse, or one period of a square wave, is shown as the driving signal in FIG. 6. As shown at the left of the plot of FIG. 6, as the driving signal increases from approximately zero (0) volts (V) to approximately 2.8 V at the rising edge of the driving signal, the sensed voltage exhibits a short-duration peak (in the positive direction). As shown at the middle of the plot of FIG. 6, as the driving signal decreases from approximately 2.8 V to approximately 0V at the falling edge of the driving signal, the sensed voltage exhibits another short-duration peak (in the negative direction). The two peaks shown are characteristics of the device.

FIG. 7 provides three plots 701, 702 and 703 of a sensed voltage at the node 13 of FIG. 5 in a simulation to show how finger touch may be detected using the techniques of the present disclosure. Each of the plots 701, 702, 703 illustrates the sensed voltage at the node 13 during a rising edge of a driving signal. The plot 701 represents sensing when there is no finger touch, the plot 702 represents sensing using the capacitors Cm of the semiconductor device package 1 of FIG. 1 when a finger is pressed on the dielectric layer 15, and the plot 703 represents sensing using the capacitors Cm′ of the semiconductor device package 2 of FIG. 2 when a finger is pressed on the dielectric layer 15. As can be seen in FIG. 7, the finger press may be detected using either the capacitors Cm of FIG. 1 or the capacitors Cm′ of FIG. 2. As can also be seen, the capacitors Cm′ of FIG. 2 provide for more change in the sensed voltage as compared to the capacitors Cm of FIG. 1.

As used herein, the terms “approximately,” “substantially,” “substantial” and “about” are used to describe and account for small variations. When used in conjunction with an event or circumstance, the terms can refer to instances in which the event or circumstance occurs precisely as well as instances in which the event or circumstance occurs to a close approximation. For example, the terms can refer to less than or equal to ±10%, such as less than or equal to ±5%, less than or equal to ±4%, less than or equal to ±3%, less than or equal to ±2%, less than or equal to ±1%, less than or equal to ±0.5%, less than or equal to ±0.1%, or less than or equal to ±0.05%. For another example, the term “substantially flat” can refer to a difference between a highest point and a lowest point of the surface of about 5 μm to about 10 μm.

Additionally, amounts, ratios, and other numerical values are sometimes presented herein in a range format. It is to be understood that such range format is used for convenience and brevity and should be understood flexibly to include numerical values explicitly specified as limits of a range, but also to include all individual numerical values or sub-ranges encompassed within that range as if each numerical value and sub-range is explicitly specified.

While the present disclosure has been described and illustrated with reference to specific embodiments thereof, these descriptions and illustrations do not limit the present disclosure. It should be understood by those skilled in the art that various changes may be made and equivalents may be substituted without departing from the true spirit and scope of the present disclosure as defined by the appended claims. The illustrations may not be necessarily drawn to scale. There may be distinctions between the artistic renditions in the present disclosure and the actual apparatus due to manufacturing processes and tolerances. There may be other embodiments of the present disclosure which are not specifically illustrated. The specification and drawings are to be regarded as illustrative rather than restrictive. Modifications may be made to adapt a particular situation, material, composition of matter, method, or process to the objective, spirit and scope of the present disclosure. All such modifications are intended to be within the scope of the claims appended hereto. While the methods disclosed herein have been described with reference to particular operations performed in a particular order, it will be understood that these operations may be combined, sub-divided, or re-ordered to form an equivalent method without departing from the teachings of the present disclosure. Accordingly, unless specifically indicated herein, the order and grouping of the operations are not limitations of the present disclosure.

1. A semiconductor device package, comprising:
a substrate having a first surface and a second surface opposite the first surface;
a first patterned conductive layer disposed on the first surface of the substrate;
an insulator layer disposed on the first surface of the substrate and covering the first patterned conductive layer;
a second patterned conductive layer encapsulated by the insulator layer; and
a first dielectric layer disposed on the insulator layer.

2. The semiconductor device package of claim 1, wherein a thickness of the insulator layer is less than 0.6 μm.

3. The semiconductor device package of claim 2, wherein the thickness of the insulator layer is 0.2 μm to 0.5 μm.

4. The semiconductor device package of claim 1, wherein the insulator layer comprises tantalum pentoxide.

5. The semiconductor device package of claim 1, wherein the insulator layer comprises a step-like structure.

6. The semiconductor device package of claim 1, further comprising a third patterned conductive layer disposed on the first surface of the substrate and covered by the insulator layer.

7. The semiconductor device package of claim 6, wherein a portion of the third patterned conductive layer is positioned over the first patterned conductive layer.

8. The semiconductor device package of claim 6, wherein a portion of the third patterned conductive layer comprises a step-like structure.

9. The semiconductor device package of claim 1, further comprising a second dielectric layer disposed on the second surface of the substrate.

10. The semiconductor device package of claim 9, further comprising a die embedded in the second dielectric layer.

11. The semiconductor device package of claim 1, wherein the second patterned conductive layer comprises a plurality of traces, and wherein each trace has a width of approximately 5 μm.

12. The semiconductor device package of claim 11, wherein a pitch of the traces is approximately 5 μm.

13-20. (canceled)

21. A semiconductor device package, comprising:
a substrate having a first surface and a second surface opposite the first surface;
a plurality of first traces disposed adjacent to the first surface of the substrate;
a plurality of second traces disposed over the plurality of first traces, the plurality of second traces crossing over the plurality of first traces to define a matrix of intersections; and
an insulator layer covering the plurality of first traces and the plurality of second traces and disposed between the plurality of first traces and the plurality of second traces,
wherein the plurality of first traces, the plurality of second traces, and the insulator layer define a matrix of capacitors located at the matrix of intersections.

22. The semiconductor device package of claim 21, wherein the insulator layer has a permittivity of 26 F/m to 26.5 F/m.

23. The semiconductor device package of claim 21, wherein the insulator layer comprises an oxide of tantalum.

24. The semiconductor device package of claim 21, further comprising:
a conductive pad disposed adjacent to the second surface of the substrate; and
a conductive post extending through the substrate and electrically connecting the conductive pad to at least one of the plurality of first traces or the plurality of second traces.

25. The semiconductor device package of claim 21, further comprising a die disposed adjacent to the second surface of the substrate.

26. The semiconductor device package of claim 25, further comprising a dielectric layer disposed adjacent to the second surface of the substrate and covering a perimeter of the die, and at least a portion of the die is exposed from the dielectric layer.

27. The semiconductor device package of claim 21, further comprising a patterned conductive layer disposed adjacent to the first surface of the substrate and covered by the insulator layer, and a portion of the patterned conductive layer is disposed over the plurality of first traces.

28. The semiconductor device package of claim 27, further comprising:
a conductive pad disposed adjacent to the second surface of the substrate; and
a conductive post extending through the substrate and electrically connecting the conductive pad to the patterned conductive layer.
